(19) United States
(12) Patent Application Publication
(10) Pub. No.: US 2026/0268953 A1
(43) Pub. Date: Sep. 10, 2026

(54) MEMORY SYSTEM

(71) Applicant: Kioxia Corporation, Tokyo (JP)

(72) Inventor: Naoki MATSUSHITA, Seoul (KR)

(73) Assignee: Kioxia Corporation, Tokyo (JP)

(21) Appl. No.: 19/235,199

(22) Filed: Jun. 11, 2025

(30) Foreign Application Priority Data
Mar. 6, 2025 (JP) 2025-035879

(51) Int. Cl. G11C 11/16; G06F 3/06

(52) U.S. Cl. CPC G11C 11/1675; G06F 3/0604; G06F 3/0655; G06F 3/0673; G11C 11/1673

(57) ABSTRACT

According to embodiments, a memory system includes a memory device and a memory controller that controls the memory device. The memory device includes a memory cell array including a plurality of word lines, a plurality of bit lines, and a plurality of memory cells each coupled to a set of one of the plurality of word lines and one of the plurality of bit lines, and a first circuit configured to, during a read operation of a first memory cell among the plurality of memory cells, sample a first voltage based on a leakage current flowing through a first bit line coupled to the first memory cell among the plurality of bit lines. The memory controller includes a second circuit configured to manage information concerning the first voltage and select an address in the memory cell array based on the information at the time of a write operation.

### CROSS-REFERENCE TO RELATED APPLICATIONS

This application is based upon and claims the benefit of priority from Japanese Patent Application No. 2025-035879, filed Mar. 6, 2025, the entire contents of which are incorporated herein by reference.

### FIELD

Embodiments described herein relate generally to a memory system.

### BACKGROUND

A memory system including a memory device that uses a variable resistance element as a memory element is known. For example, a magnetoresistive random access memory (MRAM) that uses a magnetoresistive effect element as a variable resistance element is known.

### BRIEF DESCRIPTION OF THE DRAWINGS

FIG. 1 is a block diagram showing an example of a configuration of a memory system according to the first embodiment.

FIG. 2 is a view showing an example of a configuration of a row selection circuit, a column selection circuit, and a write/read circuit included in a memory device according to the first embodiment.

FIG. 3 is a cross-sectional view showing an example of the structure of a magnetoresistive effect element included in the memory device according to the first embodiment.

FIG. 4 is a view schematically showing an example of couplings among a memory cell array, the write/read circuit, a sampling voltage circuit, and a memory controller during a read operation in the memory system according to the first embodiment.

FIG. 5 is a view showing the relationship between the number of cycles of writing/erasing in a memory cell and the threshold voltage (or hold voltage) of a selector element.

FIG. 6 is a view showing the relationship between the number of cycles of writing/erasing in a memory cell and a leakage current during a read operation.

FIG. 7 is a view showing the relationship between the number of cycles of writing/erasing in a memory cell and the failure rate of the memory cell.

FIG. 8 is a flowchart showing an example of the procedure of a read operation focusing on acquisition of a sampling voltage in the memory system according to the first embodiment.

FIG. 9 is a timing chart showing an example of voltages of respective interconnects during a read operation in the memory system according to the first embodiment.

FIG. 10 is a view showing the first example of a configuration of blocks of a memory cell array included in a memory device according to the second embodiment.

FIG. 11 is a view showing the second example of a configuration of blocks of the memory cell array included in the memory device according to the second embodiment.

FIG. 12 is a view schematically showing an example of couplings among the memory cell array, a write/read circuit, a sampling voltage circuit, and a memory controller during a read operation in the memory system according to the second embodiment.

FIG. 13 is a flowchart showing an example of the procedure of a read operation focusing on acquisition of a sampling voltage in the memory system according to the second embodiment.

### DETAILED DESCRIPTION

In general, according to one embodiment, a memory system includes a memory device and a memory controller that controls the memory device. The memory device includes a memory cell array including a plurality of word lines, a plurality of bit lines, and a plurality of memory cells each coupled to a set of one of the plurality of word lines and one of the plurality of bit lines, and a first circuit configured to, during a read operation of a first memory cell among the plurality of memory cells, sample a first voltage based on a leakage current flowing through a first bit line coupled to the first memory cell among the plurality of bit lines. The memory controller includes a second circuit configured to manage information concerning the first voltage and select an address in the memory cell array based on the information at the time of a write operation.

Embodiments will be described below with reference to the accompanying drawings. In the following description, constituent elements having the same functions and configurations are denoted by common reference numerals. In addition, a plurality of constituent elements having common reference numerals are distinguished by adding suffixes to the common reference numerals. Note that if there is no need to distinguish a plurality of constituent elements, the plurality of constituent elements are denoted by only common reference numerals without adding any suffixes. In this case, suffixes are not limited to subscripts and superscripts and include, for example, lowercase alphabets and indices meaning arrays added to the ends of reference numerals.

### 1. First Embodiment

### 1.1 Configuration

### 1.1.1 Configuration of Memory System

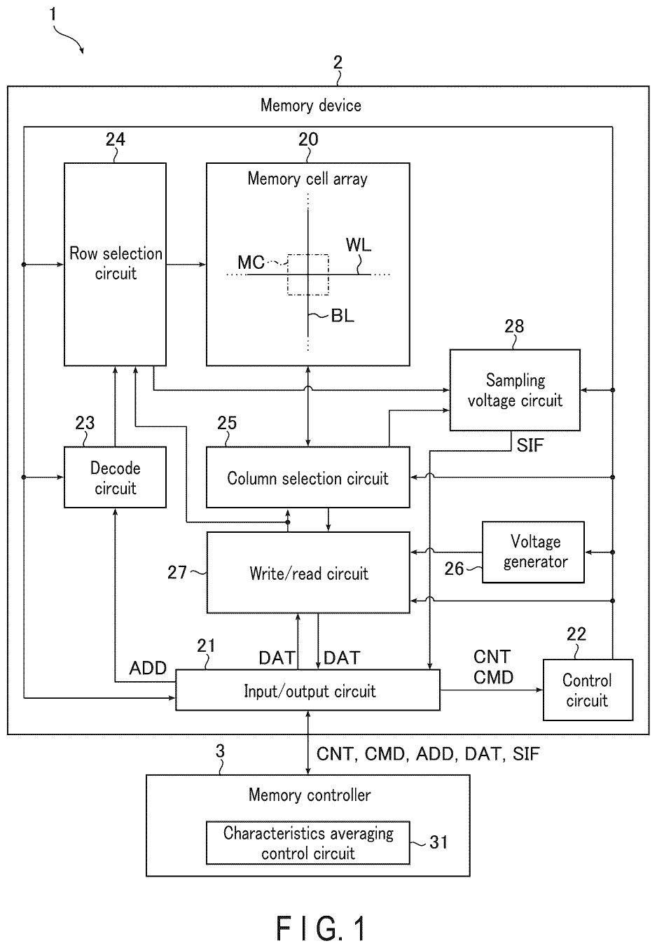

With reference to FIG. 1, a configuration of a memory system 1 according to this embodiment will be described. FIG. 1 is a block diagram showing an example of a configuration of the memory system 1 according to this embodiment.

As shown in FIG. 1, the memory system 1 includes a memory device 2 and a memory controller 3.

The memory device 2 is a memory device that stores data in a nonvolatile manner. The memory device 2 is, for example, a magnetoresistive random access memory (MRAM). For example, the MRAM uses, as a variable resistance element, an element (to be also referred to as an MTJ element or a magnetoresistive effect element) that has a magnetoresistive effect by a magnetic tunnel junction (MTJ). This is also applicable to a variable resistance element that has a property of storing different information in accordance with the resistance state. Hereinafter, a description will be given in which an MTJ element is used as the variable resistance element and, for descriptive convenience, the variable resistance element will be referred to as the magnetoresistive effect element MTJ.

The memory device 2 includes a plurality of memory cells MC. The memory device 2 stores data received from the memory controller 3 in the plurality of memory cells MC. Further, the memory device 2 outputs data read from the plurality of memory cells MC to the memory controller 3.

The memory controller 3 is a device that controls the memory device 2. The memory controller 3 is, for example, an SoC (System on a Chip). The memory controller 3 is coupled to a host (for example, a personal computer, a server system, a mobile device, an in-vehicle device, or a digital camera) (not shown). The memory controller 3 receives a request signal from the host. The memory controller 3 controls the memory device 2 based on the request signal received from the host or a spontaneous processing request.

Next, the internal configuration of the memory device 2 will be described.

The memory device 2 includes a memory cell array 20, an input/output circuit 21, a control circuit 22, a decode circuit 23, a row selection circuit 24, a column selection circuit 25, a voltage generator 26, a write/read circuit 27, and a sampling voltage circuit 28.

The memory cell array 20 is a non-volatile memory. The memory cell array 20 includes the plurality of memory cells MC each of which is associated with a set of a row and a column. The memory cell MC stores data in a nonvolatile manner. For example, the memory cells MC in the same row are coupled to the same word line WL. The memory cells MC in the same column are coupled to the same bit line BL. The memory cell array 20 includes a plurality of blocks. In this embodiment, a plurality of memory cells MC coupled to the same bit line BL are included in one block. The block is a unit for managing the degree of deterioration of the memory cell MC. Note that the block configuration can be arbitrarily set. For example, a plurality of memory cells MC coupled to a plurality of bit lines BL adjacent to each other may be included in one block.

The input/output circuit 21 is a circuit that transmits and receives data. The input/output circuit 21 receives, from the memory controller 3, a control signal CNT, a command CMD, an address ADD, and data (write data) DAT. The write data is data to be written in the memory cell array 20. The input/output circuit 21 transmits the control signal CNT and the command CMD to the control circuit 22. The input/output circuit 21 transmits the address ADD to the decode circuit 23. The input/output circuit 21 transmits the data (write data) DAT to the write/read circuit 27.

The input/output circuit 21 receives the data (read data) DAT from the write/read circuit 27. The read data is data read from the memory cell array 20. The input/output circuit 21 receives sampling information SIF based on a sampling voltage from the sampling voltage circuit 28. The sampling voltage is a voltage indicating the degree of deterioration of the sampled memory cell MC during a read operation. The sampling information SIF is information obtained by converting the sampling voltage into a digital form. The input/output circuit 21 transmits the data (read data) DAT and the sampling information SIF to the memory controller 3.

The control circuit 22 is a circuit that controls the overall operation of the memory device 2. Based on the control signal CNT and the command CMD, the control circuit 22 controls the operations of the input/output circuit 21, the decode circuit 23, the row selection circuit 24, the column selection circuit 25, the voltage generator 26, the write/read circuit 27, and the sampling voltage circuit 28.

When a command set of the read operation is received from the memory controller 3, the control circuit 22 executes the read operation. The command set of the read operation includes the read command CMD which instructs execution of the read operation, and the address ADD. Furthermore, based on the read command CMD, the control circuit 22 causes the sampling voltage circuit 28 to acquire (sample) the sampling voltage. Note that the control circuit 22 causes the sampling voltage circuit 28 to acquire the sampling voltage every time the read command CMD is received or every time K read commands CMD (K is an integer of 2 or more) are received. That is, the control circuit 22 causes the sampling voltage circuit 28 to acquire the sampling voltage every time or once every K times for a plurality of read operations.

The decode circuit 23 is a circuit that decodes the address ADD. The decode circuit 23 receives the address ADD from the input/output circuit 21. The decode circuit 23 transmits the decoding result of the address ADD to the row selection circuit 24 and the column selection circuit 25. The address ADD includes a row address and a column address.

The row selection circuit 24 is a circuit that selects the word line WL corresponding to the row of the memory cell array 20. The row selection circuit 24 is coupled to the memory cell array 20 via the word line WL. The row selection circuit 24 receives the decoding result of the address ADD (row address) from the decode circuit 23. Based on the decoding result of the address ADD, the row selection circuit 24 selects the corresponding word line WL.

The column selection circuit 25 is a circuit that selects the bit line BL corresponding to the column of the memory cell array 20. The column selection circuit 25 is coupled to the memory cell array 20 via the bit line BL. The column selection circuit 25 receives the decoding result of the address ADD (column address) from the decode circuit 23. Based on the decoding result of the address ADD, the column selection circuit 25 selects the corresponding bit line BL.

The voltage generator 26 is a circuit that generates voltages for various kinds of operations of the memory device 2 by using a power supply voltage (for example, a voltage VDD) applied from the outside of the memory device 2. The various kinds of operations are, for example, a write operation, a read operation, and an erase operation. For example, the voltage generator 26 generates a voltage (to be also referred to as a “write voltage” hereinafter) to be used in the write operation. The voltage generator 26 supplies the write voltage to the write/read circuit 27. The voltage generator 26 also generates a voltage (to be also referred to as a “read voltage” hereinafter) to be used in the read operation. The voltage generator 26 supplies the read voltage to the write/read circuit 27.

The write/read circuit 27 is a circuit that writes data in the memory cell MC and reads data from the memory cell MC.

The write/read circuit 27 includes a write driver (not shown). The write/read circuit 27 receives the write data DAT from the input/output circuit 21. The write/read circuit 27 is applied with the write voltage from the voltage generator 26. The write driver is, for example, a constant current driver. The write driver supplies a current (a current to be used in the write operation, which will be also referred to as a “write current” hereinafter) based on the write voltage to the row selection circuit 24 or the column selection circuit 25. The row selection circuit 24 supplies the write current to the memory cell array 20 via the selected word line WL. The column selection circuit 25 supplies the write current to the memory cell array 20 via the selected bit line BL.

The write/read circuit 27 also includes a read driver and a sense amplifier (not shown). The write/read circuit 27 is applied with the read voltage from the voltage generator 26. The read driver is, for example, a constant current driver. The read driver supplies a current (a current to be used during the read operation, which will be also referred to as a “read current” hereinafter) based on the read voltage to the column selection circuit 25. The column selection circuit 25 supplies the read current to the memory cell array 20 via the selected bit line BL. The sense amplifier finds the data stored in the memory cell MC based on the voltage of the bit line BL. The write/read circuit 27 transmits the found data to the input/output circuit 21 as the read data DAT.

Under the control of the control circuit 22, the sampling voltage circuit 28 acquires (samples) a sampling voltage indicating the degree of deterioration of the memory cell MC during the read operation. The sampling voltage circuit 28 in this embodiment samples a leakage current flowing through the selected bit line BL during the read operation, thereby acquiring the sampling voltage. The sampling voltage circuit 28 includes an analog to digital converter (ADC). The sampling voltage circuit 28 uses the ADC to convert the sampling voltage into a digital form, thereby generating the sampling information SIF. The sampling voltage circuit 28 transmits the generated sampling information SIF to the input/output circuit 21. Details of the configuration of the sampling voltage circuit 28 will be described later.

Next, the internal configuration of the memory controller 3 will be described.

The memory controller 3 includes a characteristics averaging control circuit 31.

The characteristics averaging control circuit 31 is a circuit that controls address selection during the write operation such that the characteristics (degrees of deterioration) of the respective memory cells MC in the memory cell array 20 are averaged. By using the sampling information SIF received from the memory device 2, the characteristics averaging control circuit 31 evaluates the degree of deterioration of the memory cell MC in the corresponding block. The characteristics averaging control circuit 31 includes, for example, a management table for managing the sampling information SIF (sampling voltage) for each block. Based on the sampling information SIF (sampling voltage) stored in the management table, the characteristics averaging control circuit 31 manages the degree of deterioration for each block. During the write operation, the characteristics averaging control circuit 31 refers to the management table and selects the block having a low sampling voltage (low degree of deterioration). With this, the characteristics (degrees of deterioration) of the respective blocks of the memory cell array 20 are averaged. The characteristics averaging control circuit 31 in this embodiment selects the bit line BL (column address) corresponding to a block BLK having a low degree of deterioration. During the write operation, the memory controller 3 transmits, to the input/output circuit 21 of the memory device 2, the address ADD corresponding to the selected block together with the write data DAT and the command CMD for the write operation.

### 1.1.2 Configuration of Memory Cell Array

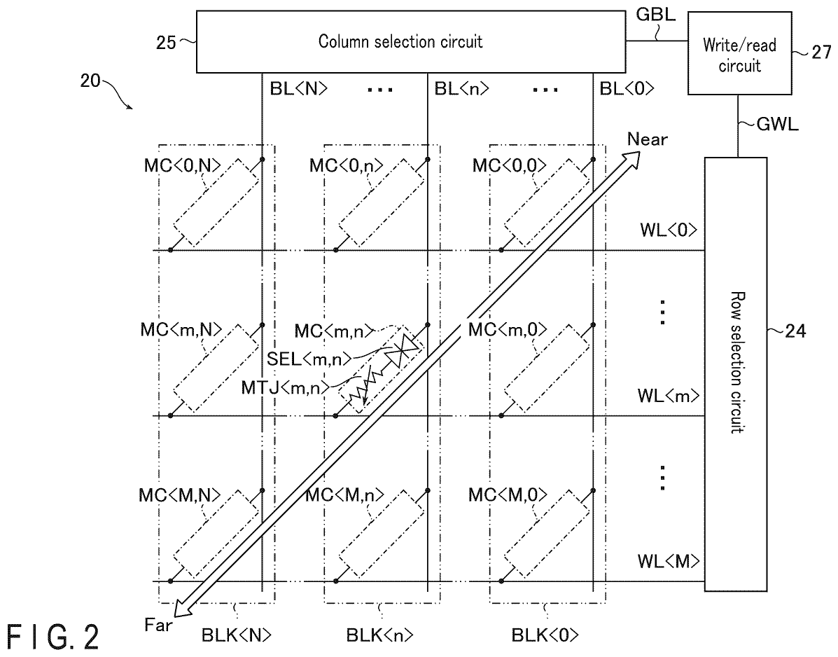

Next, with reference to FIG. 2, a configuration of the memory cell array 20 will be described. FIG. 2 is a view showing an example of a configuration of the row selection circuit 24, the column selection circuit 25, and the write/read circuit 27. Note that in FIG. 2, the memory cells MC, the word lines WL, and the bit lines BL are classified and indicated using suffixes including indices (“<>”).

As shown in FIG. 2, the memory cells MC are arranged in a matrix (grid) in the memory cell array 20. The memory cell MC is associated with a set of one of a plurality of word lines WL (WL<0>, . . . , WL<m>, . . . , WL<M>) extending in the row direction and arrayed in the column direction, and one of a plurality of bit lines BL (BL<0>, . . . , BL<n>, . . . , BL<N>) extending in the column direction and arrayed in the row direction (M and N are integers of 1 or more). That is, the memory cell MC<m, n>(0≤m≤M, 0≤n≤N) is coupled between the word line WL<m> and the bit line BL<n>.

Each word line WL<m> is coupled to the row selection circuit 24. The row selection circuit 24 is coupled to the write/read circuit 27 via a global word line GWL. Note that, in order to supply a plurality of voltages from the row selection circuit 24 to the memory cell array 20, a plurality of global word lines GWL may be provided. The row selection circuit 24 electrically couples the word line WL selected based on the row address to the global word line GWL or a ground interconnect (not shown). The ground interconnect is a grounded interconnect. Hereinafter, the selected word line WL will be referred to as the “selected word line WL”, and the other word lines WL will be referred to as the “non-selected word lines WL”.

Each bit line BL<n> is coupled to the column selection circuit 25. The column selection circuit 25 is coupled to the write/read circuit 27 via a global bit line GBL. Note that, in order to supply a plurality of voltages from the column selection circuit 25 to the memory cell array 20, a plurality of global bit lines GBL may be provided. The column selection circuit 25 electrically couples the bit line BL selected based on the column address to the global bit line GBL or the ground interconnect. Hereinafter, the selected bit line BL will be referred to as the “selected bit line BL”, and the other bit lines BL will be referred to as the “non-selected bit lines BL”.

In the memory cell array 20 in this embodiment, a plurality of memory cells MC commonly coupled to one bit line BL form one block BLK. The block BLK is a unit for managing the degree of deterioration of the memory cell MC in the characteristics averaging control circuit 31. In the example shown in FIG. 2, the memory cell array 20 includes N+1 blocks BLK<0> to BLK<N> corresponding to N+1 bit lines BL<0> to BL<N>. For example, the block BLK<n> includes M+1 memory cells MC<0, n> to MC<M, n>.

For example, a plurality of memory cells MC coupled to the same word line WL are different in the interconnect length of the word line WL coupled to the memory cell MC, that is, the resistance of the word line WL, in accordance with the address (column address) of the bit line BL. As shown in FIG. 2, for example, when the row selection circuit 24 is provided on the right side of the drawing sheet, the interconnect length of the word line WL<0> from the row selection circuit 24 to the memory cell MC<0, N> is longer than the interconnect length of the word line WL<0> from the row selection circuit 24 to the memory cell MC<0, 0>. That is, the resistance of the word line WL<0> in the memory cell MC<0, N> is higher than the resistance of the word line WL<0> in the memory cell MC<0, 0>.

Similarly, a plurality of memory cells MC coupled to the same bit line BL are different in the interconnect length of the bit line BL, that is, the resistance of the bit line BL, in accordance with the address (row address) of the word line WL. As shown in FIG. 2, for example, when the column selection circuit 25 is provided on the upper side of the drawing sheet, the interconnect length of the bit line BL<0> from the column selection circuit 25 to the memory cell MC<M, 0> is longer than the interconnect length of the bit line BL<0> from the column selection circuit 25 to the memory cell MC<0, 0>. That is, the resistance of the bit line BL<0> in the memory cell MC<M, 0> is higher than the resistance of the bit line BL<0> in the memory cell MC<0, 0>. Hereinafter, the combined resistance of the resistance of the word line WL and the resistance of the bit line BL will be simply referred to as the “interconnect resistance”. Hence, the memory cells MC have different interconnect resistances in accordance with the position in the memory cell array 20, that is the address ADD.

Hereinafter, in the memory cell array 20, the region where the memory cell MC having the relatively short interconnect lengths of the word line WL and the bit line BL, that is, the relatively low interconnect resistance is arranged will be referred to as a near side (Near). On the other hand, the region where the memory cell MC having the relatively long interconnect lengths of the word line WL and the bit line BL, that is, the relatively high interconnect resistance is arranged will be referred to as a far side (Far). In the example shown in FIG. 2, the memory cell MC<0, 0> with the smallest sum (M+N) of the column address <M> and the row address <N> is on the near side, and the memory cell MC<M, N> with the largest sum (M+N) is on the far side.

Next, the internal configuration of the memory cell MC will be described.

The memory cell MC<m, n> includes a selector element SEL<m, n> and the magnetoresistive effect element MTJ<m, n> coupled in series.

The selector element SEL is a two-terminal switching element. A two-terminal switching element is different from a three-terminal switching element such as a transistor in that it does not include the third terminal. For example, the selector element SEL contains, as constituent elements, silicon (Si), oxygen (O), and arsenic (As). For example, in a state in which no voltage is applied, the selector element SEL cuts off a current (is set in an OFF state) as an insulator having a high resistance value. When a voltage equal to or higher than a threshold voltage Vth is applied to the selector element SEL in the OFF state, it allows a current to flow (is set in an ON state) as an insulator having a low resistance value. Furthermore, when the applied voltage becomes lower than a hold voltage Vhold, the selector element SEL in the ON state is set in the OFF state. The selector element SEL switches between allowing a current to flow and cutting off a current in accordance with the magnitude of the voltage applied to the corresponding memory cell MC regardless of the polarity of the voltage applied between two terminals (regardless of the direction of the current flow).

When the memory cell MC is selected, the selector element SEL in the selected memory cell MC is set in the ON state. With this, it is possible to cause a current to flow through the magnetoresistive effect element MTJ in the selected memory cell MC.

The magnetoresistive effect element MTJ can switch the resistance value between a low resistance state and a high resistance state based on the current that flows when the selector element SEL is in the ON state. In accordance with a change of the resistance state, the magnetoresistive effect element MTJ stores data in a nonvolatile manner.

### 1.1.3 Structure of Magnetoresistance Effect Element

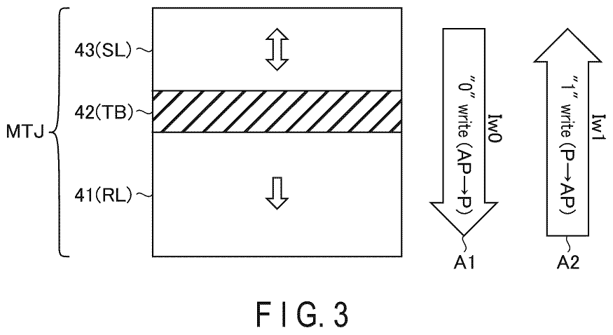

Next, with reference to FIG. 3, a structure of the magnetoresistive effect element MTJ will be described. FIG. 3 is a cross-sectional view showing an example of a structure of the magnetoresistive effect element MTJ.

As shown in FIG. 3, the magnetoresistive effect element MTJ includes a ferromagnet 41 that functions as a reference layer RL, a nonmagnet 42 that functions as a tunnel barrier layer TB, and a ferromagnet 43 that functions as a storage layer SL. For example, the ferromagnet 41, the nonmagnet 42, and the ferromagnet 43 are stacked in the order of the ferromagnet 41, the nonmagnet 42, and the ferromagnet 43 above a semiconductor substrate (not shown). Note that they may be stacked in the order of the ferromagnet 43, the nonmagnet 42, and the ferromagnet 41 above the semiconductor substrate. The magnetoresistive effect element MTJ functions as, for example, the perpendicular magnetization magnetoresistive effect element MTJ in which the magnetization direction of each magnet constituting the magnetoresistive effect element MTJ is perpendicular to the film surface.

The ferromagnet 41 has a ferromagnetic property, and has an easy axis of magnetization in a direction perpendicular to the film surface. The ferromagnet 41 contains, for example, cobalt iron boron (CoFeB) or Iron Boride (FeB). The magnetization direction of the ferromagnet 41 is fixed. In the example shown in FIG. 3, the magnetization direction of the ferromagnet 41 is directed to a surface opposite to a surface where the nonmagnet 42 is provided. Note that “the magnetization direction is fixed” means that the magnetization direction is not changed by a current (spin torque) large enough to reverse the magnetization direction of the ferromagnet 43.

The nonmagnet 42 is a nonmagnetic insulator, and contains, for example, magnesium oxide (MgO). The nonmagnet 42 is provided between the ferromagnet 41 and the ferromagnet 43. With this, the ferromagnet 41, the nonmagnet 42, and the ferromagnet 43 form a magnetic tunnel junction.

The ferromagnet 43 has a ferromagnetic property, and has an easy axis of magnetization in a direction perpendicular to the film surface. The ferromagnet 43 contains, for example, cobalt iron boron (CoFeB) or Iron Boride (FeB), and can have a body-centered cubic (bcc) crystal structure. The magnetization direction of the ferromagnet 43 is variable.

The magnetoresistive effect element MTJ can be set in either the low resistance state or the high resistance state depending on whether the relative relationship between the magnetization direction of the storage layer SL and the magnetization direction of the reference layer RL is parallel or anti-parallel. A case will be described below in which a spin injection write method is used as a method of changing the resistance state of the magnetoresistive effect element MTJ. In the spin injection write method, a spin torque is generated by causing a write current to flow through the magnetoresistive effect element MTJ. Then, by the generated spin torque, the magnetization direction of the storage layer SL with respect to the magnetization direction of the reference layer RL is controlled.

When a write current Iw0 having a certain magnitude is caused to flow through the magnetoresistive effect element MTJ in a direction of an arrow A1 in FIG. 3, that is, in a direction from the storage layer SL toward the reference layer RL, the relative relationship between the magnetization direction of the storage layer SL and the magnetization direction of the reference layer RL becomes parallel. In the parallel state, the resistance value of the magnetoresistive effect element MTJ is lowest, and the magnetoresistive effect element MTJ is set in the low resistance state. This low resistance state is called a “P (Parallel) state” and, for example, defined as a state of data “0”. Hereinafter, the operation of causing the write current to flow from the storage layer SL to the reference layer RL to set the magnetoresistive effect element MTJ in the low resistance state will be referred to as “0” write.

When a write current Iw1 larger than the write current Iw0 is caused to flow through the magnetoresistive effect element MTJ in a direction of an arrow A2 in FIG. 3, that is, in a direction from the reference layer RL toward the storage layer SL, the relative relationship between the magnetization direction of the storage layer SL and the magnetization direction of the reference layer RL becomes anti-parallel. In the anti-parallel state, the resistance value of the magnetoresistive effect element MTJ is highest, and the magnetoresistive effect element MTJ is set in the high resistance state. This high resistance state is called an “AP (Anti-Parallel) state” and, for example, defined as a state of data “1”. Hereinafter, the operation of causing the write current to flow from the reference layer RL to the storage layer SL to set the magnetoresistive effect element MTJ in the high resistance state will be referred to as “1” write.

When a read current Ir0 is caused to flow through the magnetoresistive effect element MTJ, the magnetization directions of the storage layer SL and the reference layer RL do not change. Based on the voltage of the bit line BL, the sense amplifier determines whether the resistance state of the magnetoresistive effect element MTJ is the P state or the AP state. Thus, the sense amplifier can read data from the memory cell MC.

Note that the method of defining data “0” and data “1” is not limited to the above-described example. For example, the P state may be defined as data “1”, and the AP state may be defined as data “0”.

### 1.1.4 Configuration of Sampling Voltage Circuit

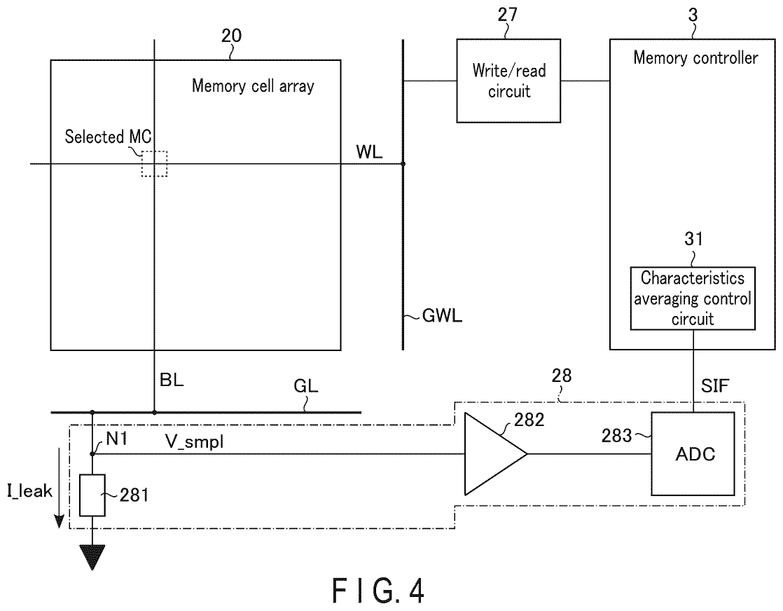

Next, with reference to FIG. 4, an example of a configuration of the sampling voltage circuit 28 will be described. FIG. 4 is a view schematically showing an example of couplings among the memory cell array 20, the write/read circuit 27, the sampling voltage circuit 28, and the memory controller 3 during the read operation. In the example shown in FIG. 4, for the sake of descriptive simplicity, the selected word line WL and the selected bit line BL are shown, and the non-selected word lines WL and the non-selected bit lines BL are not shown. In addition, the circuits other than the memory cell array 20, the write/read circuit 27, the sampling voltage circuit 28, and the characteristics averaging control circuit 31 (memory controller 3) are not shown.

As shown in FIG. 4, for example, during the read operation, the write/read circuit 27 is coupled to the selected word line WL via the global word line GWL under the control of the column selection circuit 25 (not shown). The write/read circuit 27 applies the read voltage to the memory cell MC in the selected state via the selected word line WL. Hereinafter, the memory cell MC in the selected state will be referred to as the “selected memory cell MC”, and the other memory cells MC will be referred to as the “non-selected memory cells MC”. At this time, the selected bit line BL is grounded via the ground interconnect GL under the control of the column selection circuit 25. Note that the read voltage may be applied to the selected memory cell MC from the bit line BL. In this case, the selected word line WL is grounded.

The sampling voltage circuit 28 includes a resistance element 281, an amplification circuit 282, and an ADC 283.

The resistance element 281 is a resistance element having a fixed resistance value R_ext. The R_ext can be arbitrarily set. One end of the resistance element 281 is coupled to the ground interconnect GL via a node N1, and the other end is grounded. That is, the ground interconnect GL is grounded via the resistance element 281 (applied with a ground voltage).

For example, during the read operation, a leakage current I_leak flows to the selected bit line BL. The leakage current I_leak is a leakage current that flows to the selected bit line BL from the non-selected word line WL via the non-selected memory cell MC (to be also referred to as the “semi-selected memory cell MC”) coupled to the selected bit line BL. For example, a voltage VUSEL lower than the threshold voltage Vth is applied to the non-selected word line WL and the non-selected bit line BL. Therefore, the leakage current I_leak flows to the selected bit line BL from each non-selected word line WL via the semi-selected memory cell MC.

The voltage at the node N1 during the read operation is a sampling voltage V_smpl. The sampling voltage V_smpl is calculated by an equation expressed by V_smpl=(R_ext)×(I_leak). If the leakage current I_leak increases, the sampling voltage V_smpl increases.

The amplification circuit 282 is a circuit that amplifies the sampling voltage V_smpl. An input terminal of the amplification circuit 282 is coupled to the node N1. An output terminal of the amplification circuit 282 is coupled to an input terminal of the ADC 283. Note that the amplification circuit 282 may be omitted.

The ADC 283 is a circuit that converts the sampling voltage V_smpl (amplified sampling voltage V_smpl), which is an analog voltage, into a digital form. The ADC 283 AD-converts the output voltage of the amplification circuit 282 into, for example, 4 to 8-bit digital signal. The AD-converted digital signal is the sampling information SIF. The sampling information SIF is transmitted to the characteristics averaging control circuit 31 via the input/output circuit 21.

The characteristics averaging control circuit 31 stores the sampling information SIF, that is, information of the sampling voltage V_smpl. For example, the characteristics averaging control circuit 31 uses the management table and stores the maximum value of the sampling voltage V_smpl in each block BLK. When executing the write operation, the characteristics averaging control circuit 31 refers to the management table and selects the block BLK (bit line BL) where the sampling voltage V_smpl is lowest. That is, the characteristics averaging control circuit 31 selects the block BLK (bit line BL) where the leakage current I_leak is smallest. For example, if the sampling voltage V_smpl becomes equal to or greater than a set value set in advance, the characteristics averaging control circuit 31 does not select this block BLK as the write target. The characteristics averaging control circuit 31 selects the column address corresponding to the selected block BLK (selected bit line BL). The memory controller 3 transmits, to the memory device 2, the write command CMD, the data DAT, and the address ADD including the column address selected by the characteristics averaging control circuit 31.

### 1.2 Relationship Between Number of Cycles of Writing/Erasing in Memory Cell MC and Deterioration of Memory Cell MC

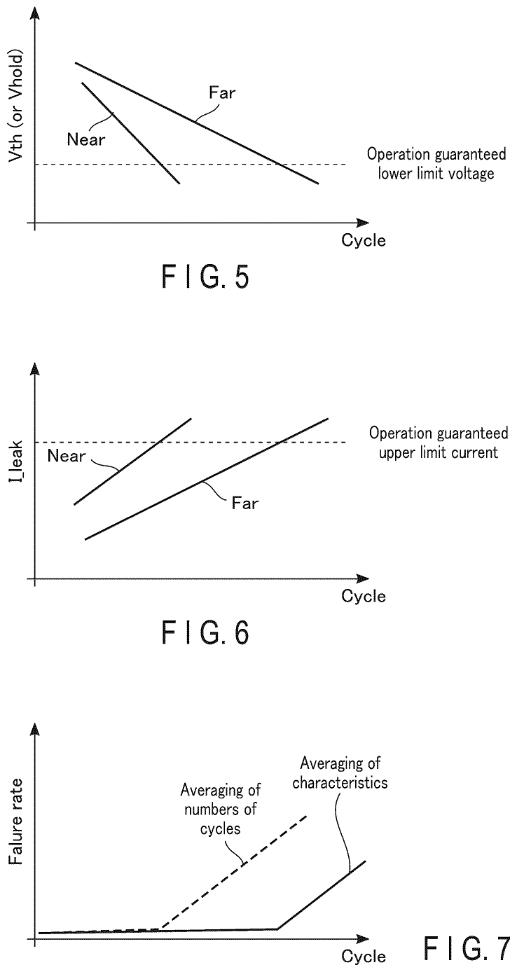

Next, with reference to FIGS. 5, 6, and 7, a relationship between the number of cycles of writing/erasing in the memory cell MC and the deterioration of the memory cell MC will be described. FIG. 5 is a view showing a relationship between the number of cycles of writing/erasing in the memory cell MC and a threshold voltage Vth (or hold voltage Vhold) of the selector element SEL. FIG. 6 is a view showing a relationship between the number of cycles of writing/erasing in the memory cell MC and the leakage current I_leak during the read operation. FIG. 7 is a view showing a relationship between the number of cycles of writing/erasing in the memory cell MC and a failure rate of the memory cell MC.

As the number of cycles of writing/erasing in the memory cell MC increases, the distribution of impurities in the selector element SEL changes. That is, the selector element SEL deteriorates. As a result, as shown in FIG. 5, along with an increase in the number of cycles, the threshold voltage Vth of the selector element SEL tends to decrease. Note that the hold voltage Vhold of the selector element SEL also tends to decrease similarly. When the threshold voltage Vth (or hold voltage Vhold) becomes lower than an operation guaranteed lower limit voltage, an operation failure of the memory cell MC occurs.

This tendency is more conspicuous in the memory cell MC on the near side (Near) than in the memory cell MC on the far side (Far). The interconnect resistance is lower in the memory cell MC on the near side than in the memory cell MC on the far side. Therefore, during the write operation or the read operation, a current flows more easily through the memory cell MC on the near side than through the memory cell MC on the far side. Accordingly, the selector element SEL of the memory cell MC on the near side deteriorates more easily (the threshold voltage Vth decreases more easily) than the selector element SEL of the memory cell MC on the far side. That is, the durability of the memory cell MC on the near side (Near) is lower than the durability of the memory cell MC on the far side (Far). In this manner, the durability against the write/erase cycle of the memory cell MC (selector element SEL) varies depending on the address in the memory cell array 20.

As shown in FIG. 6, as the number of cycles increases and the threshold voltage Vth of the selector element SEL decreases, the leakage current I_leak flowing through the selected bit line BL tends to increase during the read operation. This tendency is more conspicuous in the memory cell MC on the near side than in the memory cell MC on the far side. For example, for the same number of cycles, the leakage current I_leak of the memory cell MC on the near side is greater than the leakage current I_leak of the memory cell MC on the far side. When the leakage current I_leak increases to or above an operation guaranteed upper limit current, an operation failure can occur in the read operation.

As shown in FIG. 7, a case of averaging the numbers of cycles of writing/erasing in the respective memory cells MC will be described as a comparative example. In this case, the increase in the failure rate is rate-controlled by the memory cell MC on the near side having a low durability. When the memory cell MC (selector element SEL) on the near side having a low durability deteriorates, the failure rate abruptly increases. Therefore, the durability of the memory cell array 20 against the write/erase cycle is relatively low.

To the contrary, by executing characteristics averaging according to this embodiment, during the write operation, the memory cell MC (selector element SEL) having the low sampling voltage V_smpl (leakage current I_leak) is preferentially selected. That is, the memory cell MC (selector element SEL) where a degree of deterioration is low is preferentially selected. Accordingly, the increase in the failure rate is rate-controlled by the memory cell MC on the far side having a high durability. When the memory cell MC (selector element SEL) on the far side having a high durability deteriorates, the failure rate abruptly increases. In this manner, by averaging the characteristics (degrees of deterioration), the durability of the memory cell array 20 against the write/erase cycle becomes higher than in a case of averaging the numbers of cycles.

### 1.3 Read Operation

Next, a read operation will be described.

### 1.3.1 Procedure of Read Operation

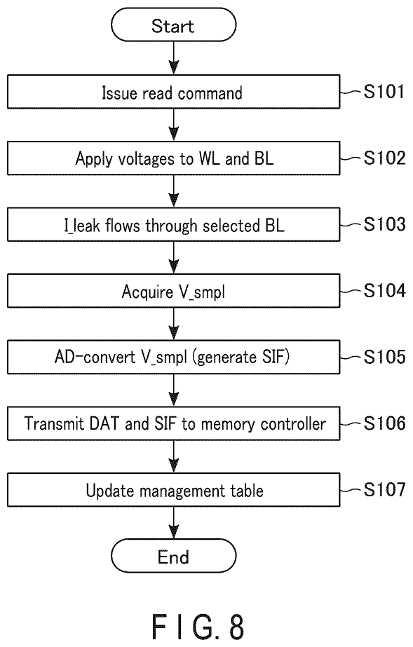

With reference to FIG. 8, an example of the procedure of a read operation focusing on acquisition of the sampling voltage will be described. FIG. 8 is a flowchart showing an example of a procedure of a read operation focusing on acquisition of the sampling voltage.

As shown in FIG. 8, first, the memory controller 3 issues the read command CMD (step S101). The memory controller 3 transmits, to the memory device 2, a command set on the read operation including the read command CMD and the address ADD. Based on the read command CMD, the control circuit 22 starts the read operation. The decode circuit 23 transmits the decoding result of the address ADD to the row selection circuit 24 and the column selection circuit 25. Based on the decoding result of the row address, the row selection circuit 24 selects the corresponding word line WL. Based on the decoding result of the column address, the column selection circuit 25 selects the corresponding bit line BL.

The write/read circuit 27 applies various kinds of voltages to the word line WL and the bit line BL via the row selection circuit 24 and the column selection circuit 25 (step S102).

At this time, the leakage current I_leak flows through the selected bit line BL (step S103).

Based on the leakage current I_leak, the sampling voltage circuit 28 acquires the sampling voltage V_smpl at the node N1 (step S104). The sampling voltage V_smpl is amplified by the amplification circuit 282, and input to the ADC 283.

The ADC 283 executes AD-conversion of the (amplified) sampling voltage V_smpl, thereby generating the sampling information SIF (step S105). The ADC 283 transmits the sampling information SIF to the input/output circuit 21.

The input/output circuit 21 (memory device 2) transmits the read data DAT and the sampling information SIF to the memory controller 3 (step S106).

The characteristics averaging control circuit 31 updates the sampling information SIF in the management table (step S107). More specifically, the characteristics averaging control circuit 31 compares the received sampling information SIF (sampling voltage V_smpl) with the sampling information SIF (sampling voltage V_smpl) of the target block BLK stored in the management table. If the received sampling voltage V_smpl is higher than the sampling voltage V_smpl stored in the management table, the characteristics averaging control circuit 31 updates the sampling information SIF for this block BLK in the management table. On the other hand, if the received sampling voltage V_smpl is equal to or lower than the sampling voltage V_smpl stored in the management table, the characteristics averaging control circuit 31 does not update the sampling information SIF for this block BLK in the management table.

### 1.3.2 Voltages of Respective Wirings During Read Operation

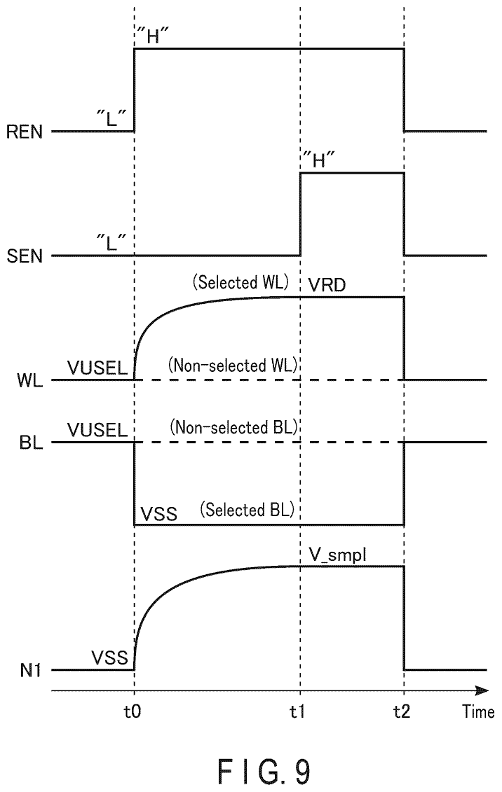

Next, with reference to FIG. 9, an example of voltages of respective interconnects during the read operation will be described. FIG. 9 is a timing chart showing an example of voltages of respective interconnects during the read operation.

As shown in FIG. 9, when a read operation is started, the voltage VUSEL is applied to each word line WL and each bit line BL. The voltage VUSEL is a voltage higher than a ground voltage VSS and lower than the threshold voltage Vth of the selector element SEL.

First, at time t0, a signal REN is changed from Low (“L”) level to High (“H”) level. The signal REN is a signal that sets the read operation in the enabled state. The selected word line WL is applied with a read voltage VRD. The read voltage VRD is a voltage higher than the threshold voltage Vth. The voltage of the non-selected word line WL is kept at the voltage VUSEL. The selected bit line BL is applied with the voltage VSS. That is, the selected bit line BL is grounded via the ground interconnect GL. The voltage of the non-selected bit line BL is kept at the voltage VUSEL.

In the period from time t0 to time t1, along with the rise of the voltage of the selected word line WL from the voltage VUSEL to the voltage VRD, the selector element SEL of the selected memory cell MC is set in the ON state. The leakage current I_leak flows through the node N1. The voltage at the node N1 rises from the voltage VSS to the voltage V_smpl.

At time t1, a signal SEN is changed from “L” level to “H” level. The signal SEN is a signal that enables a sense operation in the sense amplifier of the write/read circuit 27. In the period from time t1 to time t2, the sense amplifier reads data. In addition, the sampling voltage circuit 28 generates the sampling information SIF based on the sampling voltage V_smpl.

At time t2, the signals REN and SEN are set in “L” level. The read operation ends, and the voltage VUSEL is applied to each word line WL and each bit line BL. The voltage at the node N1 drops to VSS.

### 1.4 Effect According to This Embodiment

In the configuration according to this embodiment, the memory device 2 of the memory system 1 includes the sampling voltage circuit 28. The memory controller 3 of the memory system 1 includes the characteristics averaging control circuit 31. The sampling voltage circuit 28 can acquire the sampling voltage V_smpl based on the leakage current I_leak flowing through the selected bit line BL during the read operation. Furthermore, the sampling voltage circuit 28 can generate the sampling information SIF by AD-converting the sampling voltage V_smpl. The characteristics averaging control circuit 31 can manage the sampling information SIF for each block BLK. That is, the characteristics averaging control circuit 31 can manage the degree of deterioration of the memory cell MC (selector element SEL) for each block BLK. In the write operation, the characteristics averaging control circuit 31 can select the block BLK where the sampling voltage V_smpl is lowest, that is, the block BLK where the degree of deterioration is lowest. With this, the memory system 1 can average the characteristics (degrees of deterioration) of the memory cells MC (selector elements SEL). Hence, the memory system 1 can improve the durability against the write/erase cycle.

### 2. Second Embodiment

Next, the second embodiment will be described. In the second embodiment, a configuration of a sampling voltage circuit 28, which is different from the first embodiment, will be described. Differences from the first embodiment will be mainly described below.

### 2.1 Configuration of Blocks

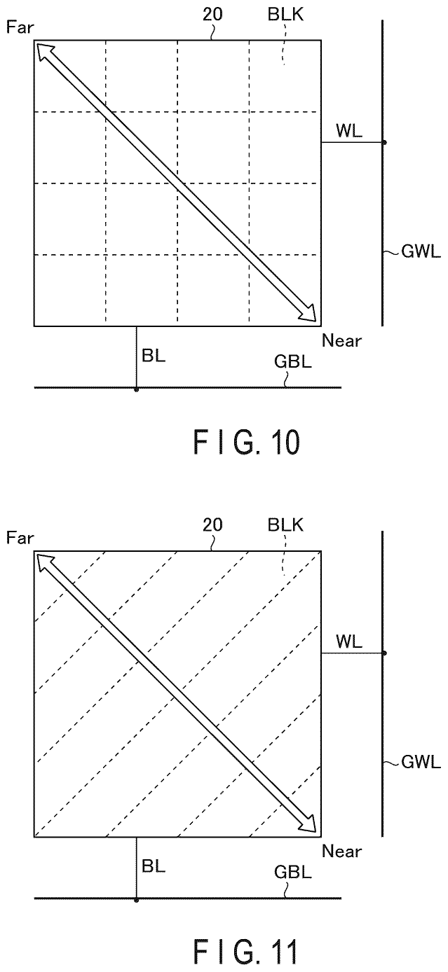

First, with reference to FIG. 10 and FIG. 11, two examples of a configuration of blocks BLK will be described. FIG. 10 is a view showing a first example of a configuration of the blocks BLK. FIG. 11 is a view showing a second example of a configuration of the blocks BLK.

First, with reference to FIG. 10, the first example will be described.

For example, the read voltage applied to the selected word line WL varies depending on the interconnect resistance of the word line WL and the bit line BL. That is, the initial value (reference voltage) of the read voltage is different for each address (memory sell MC). Therefore, as shown in FIG. 10, in the first example, a memory cell array 20 is divided into a grid such that the interconnect resistances of the word lines WL and the bit lines BL coupled to respective memory cells MC in the block BLK are almost equal (approximately the same) to each other. The number of divided blocks is arbitrary. In the example shown in FIGS. 10, 16 blocks BLK in four rows×four columns are provided. The different read voltage initial value is set for each block BLK.

Next, with reference to FIG. 11, the second example will be described.

In the second example, the memory cell array 20 is divided in accordance with the sum value (M+N) of the column address <M> and the row address <N>. The sum value (M+N) of the addresses has a correlation relationship with the sum value of the interconnect length of the word line WL and the interconnect length of the bit line BL. That is, the sum value (M+N) of the addresses has a correlation relationship with the interconnect resistance. In this case, the memory cell array 20 is divided with respect to a diagonal connecting the near side (Near) and the far side (Far) of the memory cell array 20. In the example shown in FIG. 11, eight blocks BLK which are arranged side by side in a direction connecting the near side (Near) and the far side (Far) of the memory cell array 20 are provided. Note that the number of memory cells MC included in each block BLK varies. As in the first example, the different read voltage initial value is set for each block BLK.

### 2.2 Configuration of Sampling Voltage Circuit

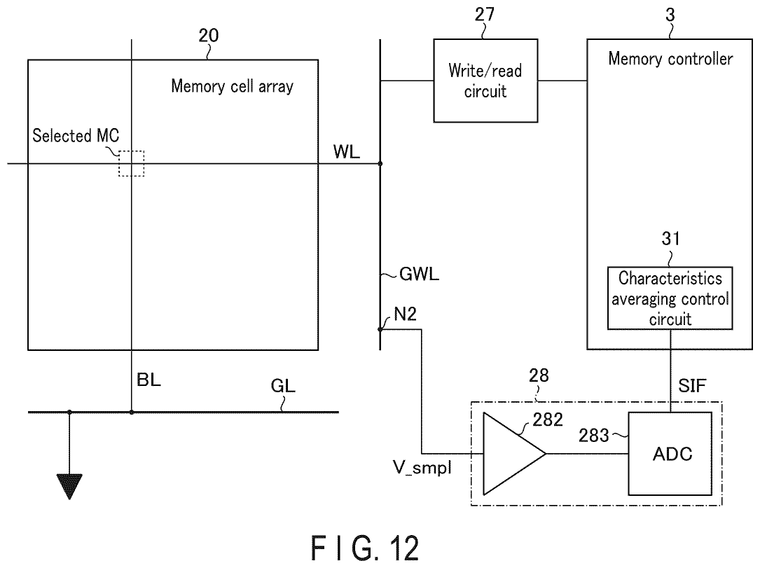

Next, with reference to FIG. 12, an example of a configuration of the sampling voltage circuit 28 will be described. FIG. 12 is a view schematically showing an example of couplings among a memory cell array 20, a write/read circuit 27, a sampling voltage circuit 28, and a memory controller 3 during the read operation. In the example shown in FIG. 12, for the sake of descriptive simplicity, the selected word line WL and the selected bit line BL are shown, and the non-selected word lines WL and the non-selected bit lines BL are not shown. In addition, the circuits other than the memory cell array 20, the write/read circuit 27, the sampling voltage circuit 28, and a characteristics averaging control circuit 31 (memory controller 3) are not shown.

The configurations of the memory cell array 20, an input/output circuit 21, a control circuit 22, a decode circuit 23, a row selection circuit 24, a column selection circuit 25, a voltage generator 26, and the write/read circuit 27 are similar to those in the first embodiment.

As shown in FIG. 12, the sampling voltage circuit 28 includes an amplification circuit 282 and an ADC 283.

In this embodiment, during the read operation, the read voltage applied to the selected word line WL is acquired as a sampling voltage V_smpl. For example, the read voltage corresponds to the threshold voltage Vth (or the hold voltage Vhold) of the selected memory cell MC. Therefore, when the threshold voltage Vth of the memory cell MC decreases, the read voltage, that is, the sampling voltage V_smpl decreases. In this embodiment, by sampling the difference between the initial value and the read voltage (sampling voltage V_smpl), the degree of deterioration of the memory cell MC is evaluated.

An input terminal of the amplification circuit 282 in this embodiment is coupled to a node N2 provided on a global word line GWL. An output terminal of the amplification circuit 282 is coupled to an input terminal of the ADC 283. Note that the amplification circuit 282 may be omitted.

The ADC 283 is similar to that in the first embodiment. The ADC 283 transmits sampling information SIF to the characteristics averaging control circuit 31.

The read voltage initial value is different for each block BLK. Therefore, the characteristics averaging control circuit 31 in this embodiment calculates the difference between the read voltage initial value and the sampling voltage V_smpl for each block BLK. The characteristics averaging control circuit 31 stores the difference for each block BLK by using a management table. When executing the write operation, the characteristics averaging control circuit 31 refers to the management table, and selects the block BLK where the difference is smallest. For example, if the difference becomes equal to or larger than a set value set in advance, the characteristics averaging control circuit 31 does not select this block BLK as the write target. In this embodiment, the addresses of the word line WL and the bit line BL (that is, the row address and the column address) are different for each block BLK. Therefore, in the write operation, the characteristics averaging control circuit 31 selects an address ADD (row address and column address) corresponding to the selected block BLK. The memory controller 3 transmits a write command CMD, data DAT, and the address ADD selected by the characteristics averaging control circuit 31 to a memory device 2.

### 2.3 Procedure of Read Operation

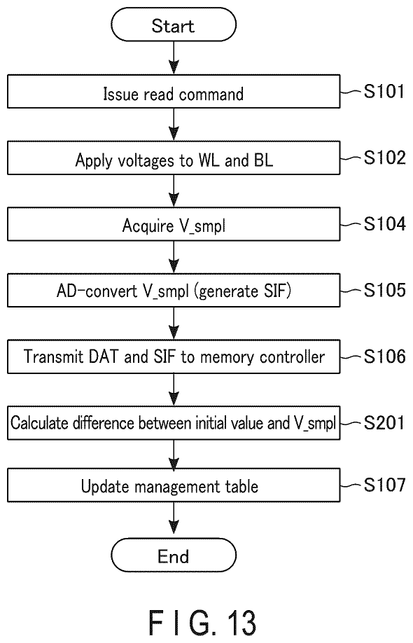

Next, with reference to FIG. 13, an example of the procedure of a read operation focusing on acquisition of the sampling voltage will be described. FIG. 13 is a flowchart showing an example of the procedure of a read operation focusing on acquisition of the sampling voltage.

As shown in FIG. 13, the operations in steps S101 and S102 are similar to those described with reference to FIG. 8 in the first embodiment.

The sampling voltage circuit 28 acquires the sampling voltage V_smpl based on the read voltage (step S104). The sampling voltage V_smpl is amplified by the amplification circuit 282, and input to the ADC 283.

The operations in steps S105 and S106 are similar to those described with reference to FIG. 8 in the first embodiment.

Based on the received sampling information SIF (sampling voltage V_smpl), the characteristics averaging control circuit 31 calculates the difference between the initial value of the target block BLK and the sampling voltage V_smpl (step S201).

The characteristics averaging control circuit 31 updates the information of the difference in the management table (step S107). More specifically, the characteristics averaging control circuit 31 compares the difference based on the received sampling information SIF (sampling voltage V_smpl) with the difference for the target block BLK stored in the management table. If the difference based on the received sampling voltage V_smpl is larger than the difference stored in the management table, the characteristics averaging control circuit 31 updates the information of the difference for this block BLK in the management table. On the other hand, if the difference based on the received sampling voltage V_smpl is equal to or smaller than the difference stored in the management table, the characteristics averaging control circuit 31 does not update the information of the difference for this block BLK in the management table.

### 2.4 Effect According to This Embodiment

With the configuration according to this embodiment, an effect similar to that of the first embodiment can be obtained.

### 3. Modifications

“Coupling” in the embodiments described above includes indirect coupling intervening something else, for example, a transistor, a resistor, or the like.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device that includes:
a memory cell array including a plurality of word lines, a plurality of bit lines, and a plurality of memory cells each coupled to a set of one of the plurality of word lines and one of the plurality of bit lines; and
a first circuit configured to, during a read operation of a first memory cell among the plurality of memory cells, sample a first voltage based on a leakage current flowing through a first bit line coupled to the first memory cell among the plurality of bit lines; and
a memory controller that includes a second circuit configured to manage information concerning the first voltage and select an address in the memory cell array based on the information at the time of a write operation, and controls the memory device.

2. The system according to claim 1, wherein
the first circuit includes an AD (analog to digital) converter configured to generate the information digitalized based on the first voltage.

3. The system according to claim 1, wherein
during the write operation, the second circuit selects a column address corresponding to one of the plurality of bit lines.

4. The system according to claim 1, wherein
the memory cell array is divided into a plurality of blocks for each bit line, and
the second circuit manages the information for each block.

5. The system according to claim 4, wherein
the plurality of blocks include a first block corresponding to the first bit line, and
in a case in which the first voltage based on the read operation of the first memory cell is higher than a second voltage corresponding to the first block stored in the second circuit, the second circuit updates the information corresponding to the first block from the second voltage to the first voltage.

6. The system according to claim 1, wherein
the information indicates degrees of deterioration of the plurality of memory cells.

7. The system according to claim 1, wherein
the first circuit executes the sampling every time the memory device receives a read command instructing the read operation K times (K is an integer equal to or more than 2) from the memory controller.

8. The system according to claim 2, wherein
the first circuit further includes a resistance element, and
during the read operation of the first memory cell, the first bit line is grounded via the resistance element.

9. The system according to claim 1, wherein
each of the plurality of memory cells includes a variable resistance element and a switching element coupled in series.

10. The system according to claim 9, wherein
the variable resistance element is a magnetoresistive effect element.

11. A memory system comprising:
a memory device that includes:
a memory cell array including a plurality of word lines, a plurality of bit lines, and a plurality of memory cells each coupled to a set of one of the plurality of word lines and one of the plurality of bit lines; and
a first circuit configured to, during a read operation of a first memory cell among the plurality of memory cells, sample a first voltage applied to a first word line coupled to the first memory cell among the plurality of word lines; and
a memory controller that includes a second circuit configured to manage information concerning the first voltage and select an address in the memory cell array based on the information at the time of a write operation, and controls the memory device.

12. The system according to claim 11, wherein
the first circuit includes an AD (analog to digital) converter configured to generate the information digitalized based on the first voltage.

13. The system according to claim 11, wherein
during the write operation, the second circuit selects a column address corresponding to one of the plurality of bit lines and a row address corresponding to one of the plurality of word lines.

14. The system according to claim 11, wherein
the memory cell array is divided into a plurality of blocks in a grid, and
the second circuit manages the information for each block.

15. The system according to claim 11, wherein
the plurality of bit lines include M+1 (M is an integer equal to or more than 1) bit lines as 0th to Mth bit lines,
the plurality of word lines include N+1 (N is an integer equal to or more than 1) word lines as 0th to Nth word lines,
the memory cell array is divided into a plurality of blocks based on a sum value of M+N, and
the second circuit manages the information for each block.

16. The system according to claim 11, wherein
the memory cell array is divided into a plurality of blocks, and
the second circuit manages, as the information, a difference between the first voltage and a preset initial value for each block.

17. The system according to claim 16, wherein
the plurality of blocks include a first block corresponding to the first memory cell, and
in a case in which a first difference calculated based on the read operation of the first memory cell is larger than a second difference corresponding to the first block stored in the second circuit, the second circuit updates the information corresponding to the first block from the second difference to the first difference.

18. The system according to claim 11, wherein
the information indicates degrees of deterioration of the plurality of memory cells.

19. The system according to claim 11, wherein
the first circuit executes the sampling every time the memory device receives a read command instructing the read operation K times (K is an integer equal to or more than 2) from the memory controller.

20. The system according to claim 11, wherein
each of the plurality of memory cells includes a variable resistance element and a switching element coupled in series.

21. The system according to claim 20, wherein
the variable resistance element is a magnetoresistive effect element.
